(19) United States
(12) Patent Application Publication
(10) Pub. No.: US 2020/0228688 A1
(43) Pub. Date: Jul. 16, 2020

(54) ELECTRONIC APPARATUS

(71) Applicant: LENOVO (SINGAPORE) PTE. LTD., SINGAPORE (SG)

(72) Inventors: Shigehiro Horiuchi, YOKOHAMA (JP); Takehito Yamauchi, YOKOHAMA (JP); Shinichi Kubota, YOKOHAMA (JP); Satoshi Hosoya, YOKOHAMA (JP)

(73) Assignee: LENOVO (SINGAPORE) PTE. LTD., SINGAPORE (SG)

(21) Appl. No.: 16/450,401

(22) Filed: Jun. 24, 2019

(30) Foreign Application Priority Data
Jan. 11, 2019 (JP) 2019003421

(51) Int. Cl. H04N 5/225; H05K 7/14; G03B 11/04; G10K 11/00; G03B 31/00; G06F 1/16

(52) U.S. Cl. CPC H04N 5/2257; H04N 5/2252; H05K 7/14; G06F 1/1633; G03B 11/045; G10K 11/002; G03B 31/00; H04N 5/2254

(57) ABSTRACT

An electronic apparatus includes a lens cover unit that is installed so as to be able to move between a first position where a transmission window overlaps with a lens of a camera and at least one of multiple switches is put into an ON state and a second position where a portion other than the transmission window covers the lens of the camera and the multiple switches are put into an OFF state.

### FIELD OF THE INVENTION

The present invention relates to an electronic apparatus.

### BACKGROUND OF THE INVENTION

For example, a laptop PC (hereinafter, referred to as a “laptop”) is known as an electronic apparatus equipped with functional components such as a camera and a microphone.

For example, a camera built into a laptop according to Japanese Unexamined Patent Application Publication No. 2016-21259 is controlled by a CPU, and takes an image of a user, etc. in front of a display panel (a display). This sort of built-in camera is convenient for being used, for example, as a Web camera for video chat. Meanwhile, from the viewpoint of security, you may sometimes want the camera to be physically covered. As an external accessory meeting such a need, a camera cover has been on the market. For example, a certain camera cover is stuck on an upper part of a display, and is configured to be slidable between a position to cover a camera and a position not to cover the camera.

### SUMMARY OF THE INVENTION

The above-described laptop has a camera cover that can prevent the camera from taking an image of the user, etc. even when hacked by a remote third person through a network and can protect the user's privacy. However, Japanese Unexamined Patent Application Publication No. 2016-21259 does not describe that a microphone is equipped with a privacy function. While strengthening the protection for user's privacy has been desired recently, if a member of the same sort as the above-described camera cover is provided separately with the intention of equipping the microphone with the privacy function, the user needs to operate multiple members, and the operation becomes cumbersome, and further, the structure becomes complicated.

Accordingly, the present invention is intended to provide an electronic apparatus capable of strengthening the protection for user's privacy without making the operation cumbersome and making the structure complicated.

An electronic apparatus according to an aspect of the present invention includes: a chassis; a camera installed in the chassis; a microphone installed in the chassis; multiple switches that are provided in parallel with the camera to put the microphone into ON state or OFF state; and a sliding member provided with a transmission window configured to let light to a lens of the camera therethrough on its main body part, in which the sliding member is installed so as to be able to move between a first position where the transmission window overlaps with the lens of the camera and at least one of the multiple switches is put into ON state and a second position where a portion of the main body part other than the transmission window covers the lens and the switches are put into OFF state.

According to the above-described aspect, by causing the sliding member to move to the first position or the second position, light received by the lens of the camera can be cut off, or the microphone can be put into the OFF state. For example, when the sliding member is in the second position, the sliding member can cut off light received by the lens of the camera, and can put the microphone into the OFF state. In this way, by operating only the single sliding member, light received by the lens of the camera can be cut off, or the microphone can be put into the OFF state; therefore, it is possible to strengthen the protection for user's privacy without making the operation cumbersome and making the structure complicated.

The above-described aspect of the present invention can provide an electronic apparatus capable of strengthening the protection for user's privacy without making the operation cumbersome and making the structure complicated.

### BRIEF DESCRIPTION OF THE DRAWINGS

FIG. 1 is a perspective view showing a laptop (an electronic apparatus) according to an embodiment.

FIG. 2 is a block diagram showing a hardware configuration of the laptop according to the embodiment.

FIG. 3 is a block diagram showing a functional configuration of the laptop according to the embodiment.

FIG. 4A is a front view showing a part II of the laptop shown in FIG. 1.

FIG. 4B is an explanatory diagram showing an ON/OFF state of the detection switch when a lens cover unit is in a position shown in FIG. 4A.

FIG. 5A is a front view showing the part II of the laptop shown in FIG. 1.

FIG. 5B is an explanatory diagram showing the ON/OFF state of the detection switch when the lens cover unit is in a position shown in FIG. 5A.

FIG. 6A is a front view showing the part II of the laptop shown in FIG. 1.

FIG. 6B is an explanatory diagram showing the ON/OFF state of the detection switch when the lens cover unit is in a position shown in FIG. 6A.

FIGS. 7A-C are schematic diagrams showing an example of a power circuit that supplies electric power to a camera and a microphone.

FIG. 8A is a front view showing the part II of the laptop shown in FIG. 1.

FIG. 8B is an explanatory diagram showing the ON/OFF state of the detection switch when the lens cover unit is in a position shown in FIG. 8A.

FIG. 9A is a front view showing the part II of the laptop shown in FIG. 1.

FIG. 9B is an explanatory diagram showing the ON/OFF state of the detection switch when the lens cover unit is in a position shown in FIG. 9A.

FIG. 10A is a front view showing the part II of the laptop shown in FIG. 1.

FIG. 10B is an explanatory diagram showing the ON/OFF state of the detection switch when the lens cover unit is in a position shown in FIG. 10A.

FIGS. 11A-C are schematic diagrams showing another example of the power circuit that supplies electric power to the camera and the microphone.

### DETAILED DESCRIPTION OF THE INVENTION

A preferred embodiment of the present invention will be described with reference to accompanying drawings. It is to be noted that in the drawings, components with the same reference numeral have the same or similar configuration.

The following embodiment is an example where the present invention is applied to a laptop. The present invention is applicable to various electronic apparatuses such as desktop computers, tablet computers, and smartphones, besides laptops.

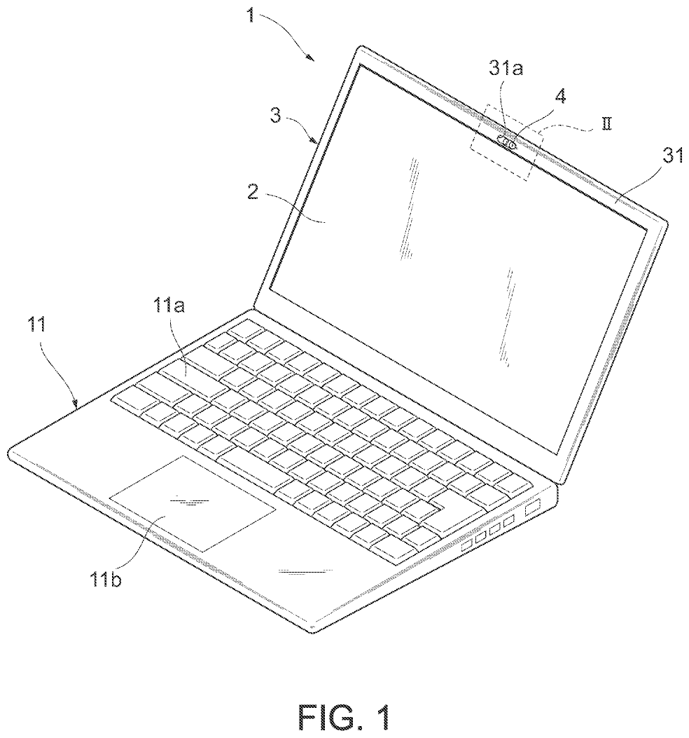

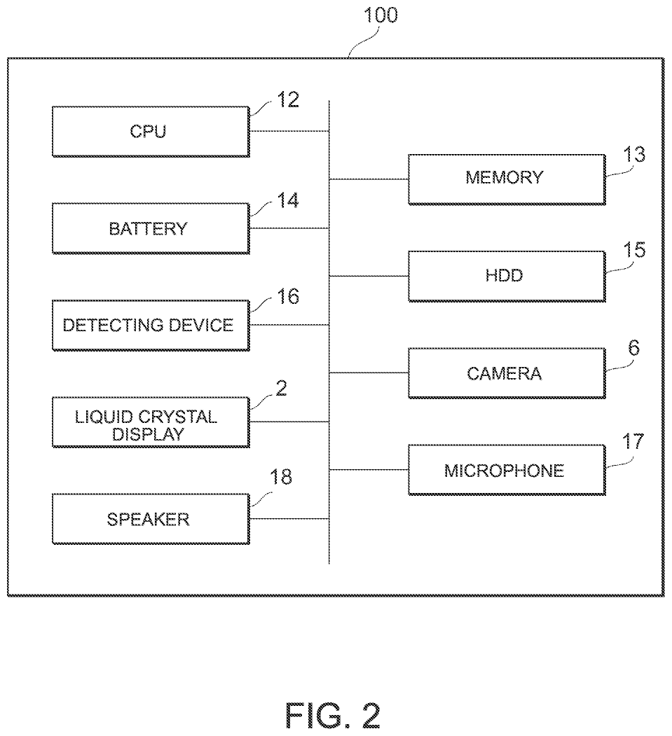

A configuration of a laptop (an electronic apparatus) 1 according to the present embodiment is described with reference to FIGS. 1 and 2. FIG. 1 is a perspective view illustrating the exterior appearance of the laptop 1. FIG. is a schematic block diagram illustrating a hardware configuration of the laptop 1.

As shown in FIG. 1, the laptop 1 has a main body chassis 11 and a cover chassis 3 that is connected to an end of the main body chassis 11 by hinges and is openable and closable with respect to the main body chassis 11. Furthermore, an upper end of the standing cover chassis 3 is provided with a camera 6 (not shown) and a lens cover unit 4 that covers a lens of the camera 6.

The main body chassis 11 has a shape of a flattened box. Inside the main body chassis 11, a circuit board, various electronic devices to be described later, etc. are housed, although not shown in FIG. 1. On the top of the main body chassis 11, input devices such as a keyboard 11a and a touchpad 11b that receive an input from the user are provided. It is to be noted that the main body chassis 11 and the cover chassis 3 are referred to collectively as a “chassis”.

The cover chassis 3 is made of a resin material, and houses therein electronic components such as a liquid crystal display 2. While in a closed state, the cover chassis 3 covers and protects the keyboard 11a, etc. Furthermore, while in an open state, the cover chassis 3 stands as shown in FIG. 1 to expose the keyboard 11a, etc. Hereinafter, in a state where the cover chassis 3 stands, a direction from the side of the cover chassis 3 to the user side is referred to as a “front direction”, and a right-left direction viewed from the user facing the cover chassis 3 is referred to as a “width direction”.

The cover chassis 3 has a bezel 31. The bezel 31 is a frame body, and the liquid crystal display 2 is exposed through this frame. A long hole 31a is formed on an upper end of the bezel 31 of the standing cover chassis 3 (hereinafter, referred to as “the upper end of the bezel 31”) and substantially at the center in the width direction. The lens cover unit 4 is installed in the long hole 31a.

As shown in FIG. 2, the laptop 1 includes, for example, a CPU (a processor) 12, a memory 13, a battery 14, an HDD 15, a detecting device 16, the camera 6, the liquid crystal display 2, a microphone 17, and a speaker 18.

The CPU 12 includes an arithmetic logic unit and various registers (a program counter, a data register, a control register or a general-purpose register, etc.). The CPU 12 executes, for example, an operating system program, a driver program, an application program, etc. (hereinafter, also referred to collectively as “various programs”), thereby outputting a result of predetermined arithmetic processing and realizing various functions of a control unit 110 of the laptop 1 to be described later. The CPU 12 is an example of the control unit 110.

The memory 13 is, for example, a storage medium such as a random access memory (RAM). The memory 13 temporarily stores therein program codes of various programs executed by the CPU 12 and data required to execute the various programs. The memory 13 stores therein, for example, a camera application for displaying an operation screen on the liquid crystal display 2. The operation screen is a screen displayed on the liquid crystal display 2 for the user to operate the camera 6, and through which an operation input from the user for, for example, setting the brightness of the camera 6, switching to a still image or a moving image mode, or setting the aspect ratio of a shooting image is received and reflected in the camera 6. Furthermore, the camera application is an application program for controlling the camera 6 in accordance with an operation input received through the operation screen.

The HDD 15 is a non-volatile storage medium. The HDD 15 stores therein various programs and various data. Such programs and data are loaded into the memory 13 as needed and browsed by the CPU 12.

The microphone 17 is an input device that is installed in the main body chassis 11 to detect ambient sound. The microphone 17 may be provided outside the main body chassis 11 through an input-output I/F.

The speaker 18 is an output device that is installed in the main body chassis 11 to output sound. The speaker 18 may be replaced by a device for outputting sound to a headphone or an earphone.

The detecting device 16 has a function of detecting an open/closed state of the lens cover unit 4 with respect to the lens of the camera 6. Specifically, the detecting device 16 detects whether the lens cover unit 4 is in a position where a portion of the lens cover unit 4 other than a transmission window 44 covers the lens of the camera 6 or in a position where the transmission window 44 overlaps with the lens of the camera 6. As will be described later, on the basis of a result of the detection by the detecting device 16, a device control unit 111 performs control of the activation or deactivation of the camera 6.

The camera 6 is a photographing device that has a lens and an image sensor and generates image data by receiving light. The camera 6 is mounted on a circuit board (not shown).

The liquid crystal display 2 is an example of a display. The liquid crystal display 2 is installed in the cover chassis 3, and displays a variety of information on the basis of an input received by the keyboard 11a or the touchpad 11b. Specifically, first, a graphics controller (not shown) performs a predetermined operation on the basis of an input received by the keyboard 11a or the like, and transmits a control signal corresponding to a result of the operation to the liquid crystal display 2. The liquid crystal display 2 receives the control signal, and displays an image or text.

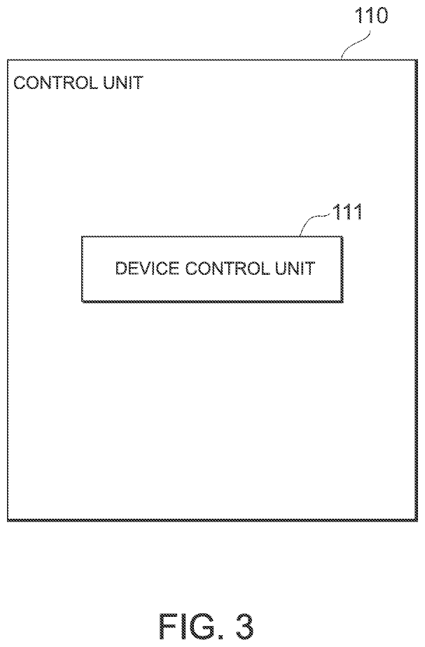

A functional configuration of the laptop 1 is described with reference to FIG. 3. The control unit 110 of the laptop 1 includes, for example, the device control unit 111.

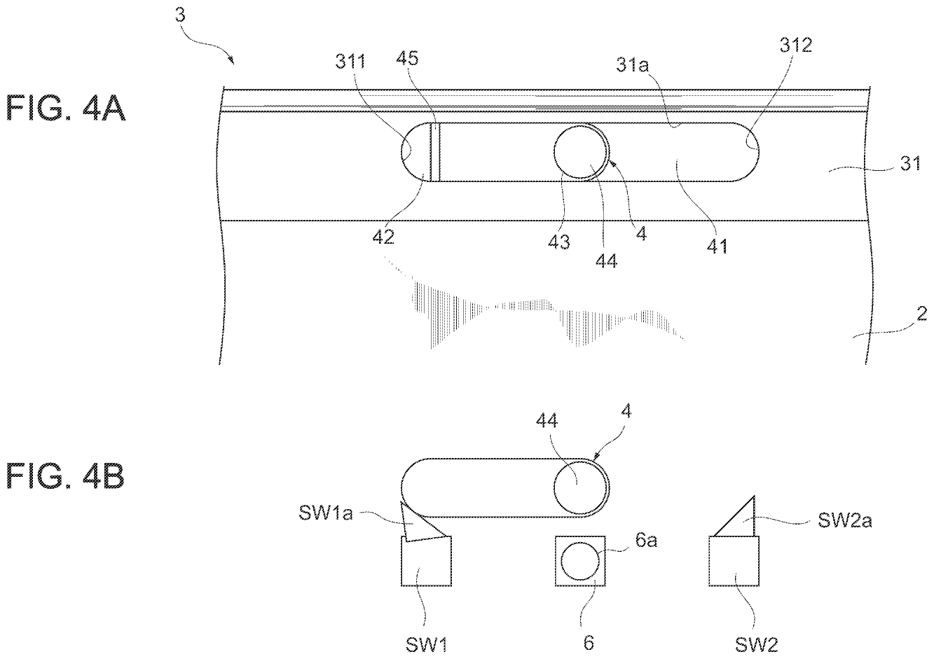

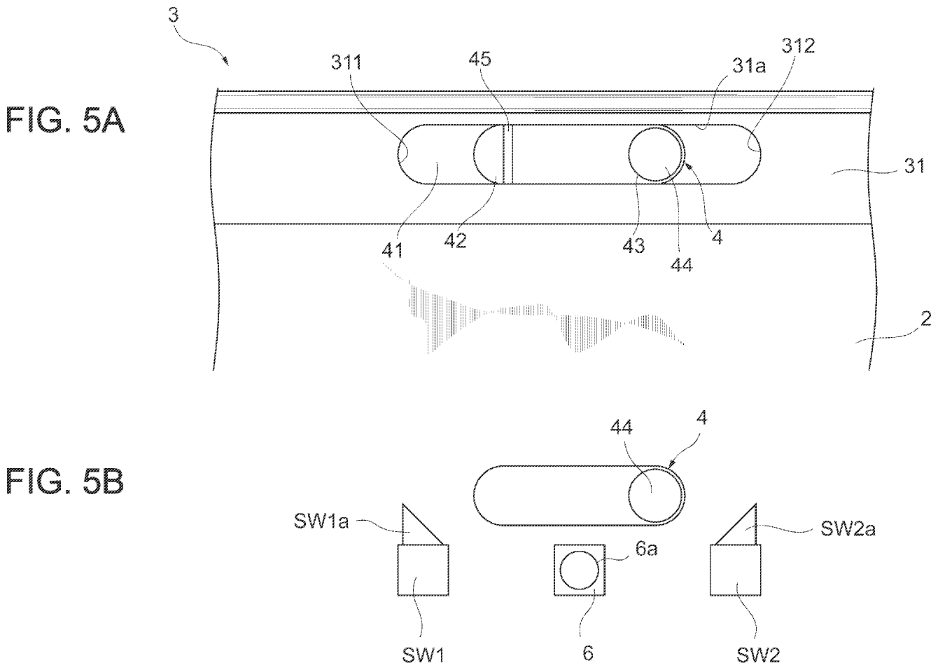

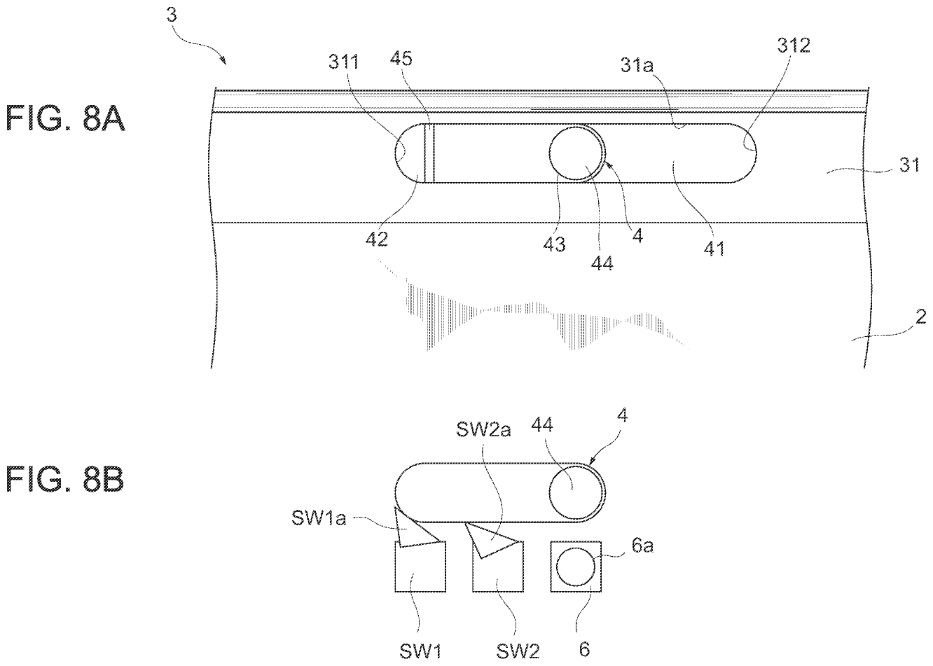

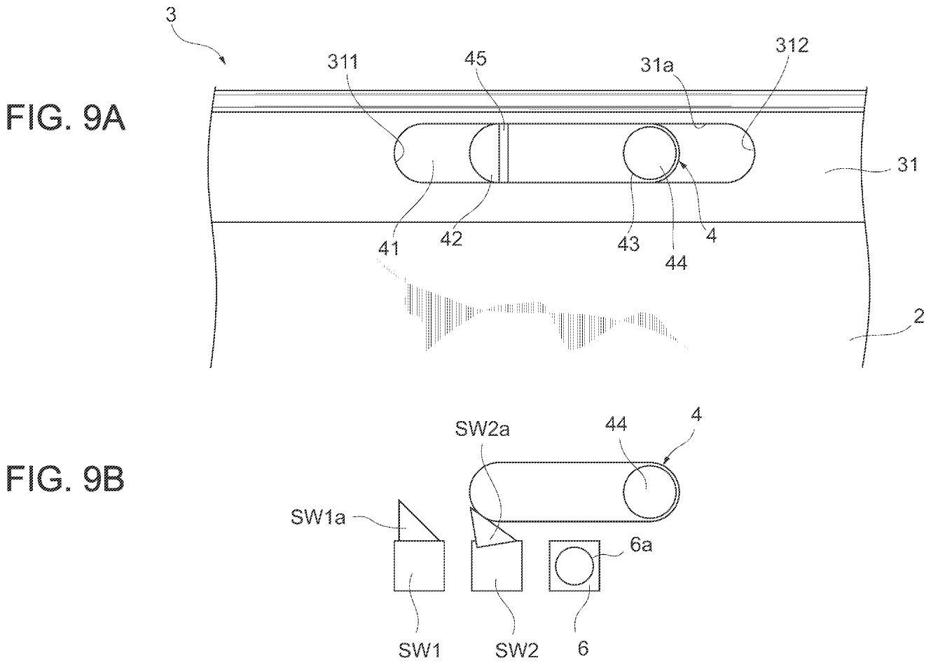

In an aspect shown in FIGS. 4 to 6 to be described later, the device control unit 111 activates the camera 6 on the basis of an output from the detecting device 16 that has detected that the lens cover unit 4 has moved from a second position (see FIG. 5) to a first position (see FIG. 4), and deactivates the camera 6 on the basis of an output from the detecting device 16 that has detected that the lens cover unit 4 has moved from the first position (see FIG. 4) to the second position (see FIG. 5). Furthermore, an aspect shown in FIGS. 8 to 10 to be described later, the device control unit 111 activates the camera 6 on the basis of an output from the detecting device 16 that has detected that the lens cover unit 4 has moved from a third position (see FIG. 9) to the first position (see FIG. 8), and deactivates the camera 6 on the basis of an output from the detecting device 16 that has detected that the lens cover unit 4 has moved from the first position (see FIG. 8) to the third position (see FIG. 9). With such a configuration, the camera 6 can be activated or deactivated by moving the lens cover unit 4 along a longitudinal direction of the long hole 31a. It is to be noted that details of an ON/OFF state switching operation of the microphone 17, including the activation or deactivation of the camera 6, will be described later.

The lens cover unit 4 shown in FIGS. 4, etc. is a thin plate-like member made of a resin material. The lens cover unit 4 has a thin portion 41 and a thick portion 42. The thick portion 42 is thicker than the thin portion 41. Both ends of the thick portion 42 have a shape of a circular arc having the radius substantially equal to ends 311 and 312 of the long hole 31a of the bezel 31.

A through hole 43 is formed on the thick portion 42; the through hole 43 goes through the thick portion 42 in a thickness direction. The transmission window 44 (a translucent cover) is fitted into the through hole 43. The transmission window 44 is made of a resin material, such as polyethylene terephthalate, polystyrene, polypropylene, and acrylic, or a material such as glass that lets visible light therethrough. Furthermore, a groove 45 is formed on, of an outer surface of the thick portion 42, a section on the side of the through hole 43. The groove 45 extends linearly.

The lens cover unit 4 is capable of sliding movement in the width direction (i.e., the longitudinal direction of the long hole 31a). This sliding movement enables the lens cover unit 4 to be set in the first position, the second position, or the third position to be described later.

Subsequently, a function of the lens cover unit 4 is described with reference to FIGS. 4 to 6. FIGS. 4 to 6 show an example of a configuration in which detection switches SW1 and SW2 for putting the microphone 17 into ON state or OFF state are provided on both sides of the camera 6 (the detection switch SW1 is provided on the left of the camera 6, and the detection switch SW2 is provided on the right of the camera 6).

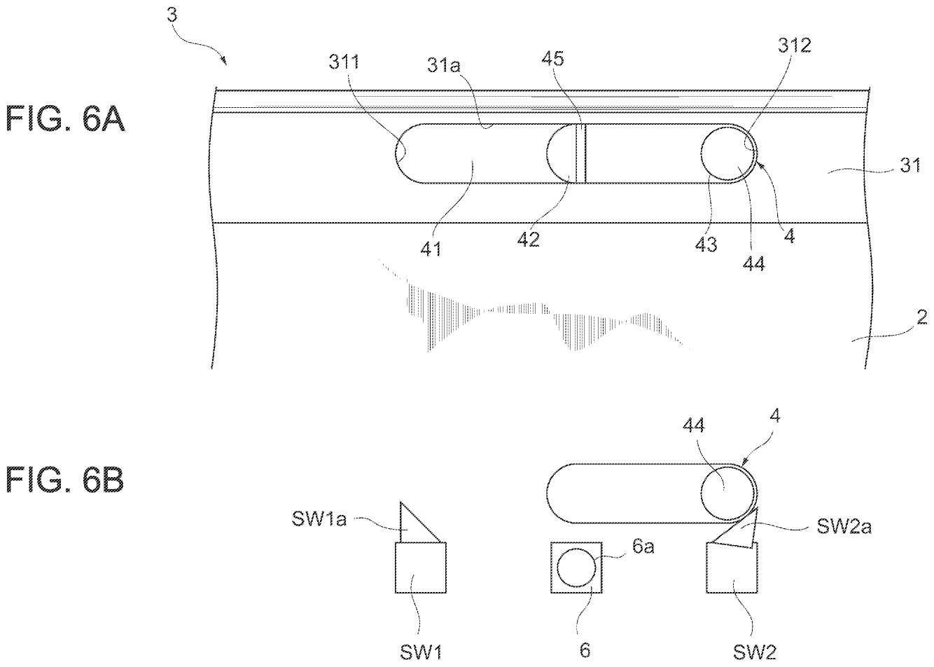

FIG. 4 shows a state where the lens cover unit 4 is set in the first position. FIG. 4A is a front view of a part II shown in FIG. 1. FIG. 4B is an explanatory diagram showing respective ON/OFF states of the detection switches SW1 and SW2 when the lens cover unit 4 is in a position shown in FIG. 4A. FIG. 5 shows a state where the lens cover unit 4 is set in the second position. FIG. 5A is a front view of the part II shown in FIG. 1. FIG. 5B is an explanatory diagram showing the ON/OFF states of the detection switches SW1 and SW2 when the lens cover unit 4 is in a position shown in FIG. 5A. FIG. 6 shows a state where the lens cover unit 4 is set in the third position. FIG. 6A is a front view of the part II shown in FIG. 1. FIG. 6B is an explanatory diagram showing the ON/OFF states of the detection switches SW1 and SW2 when the lens cover unit 4 is in a position shown in FIG. 6A.

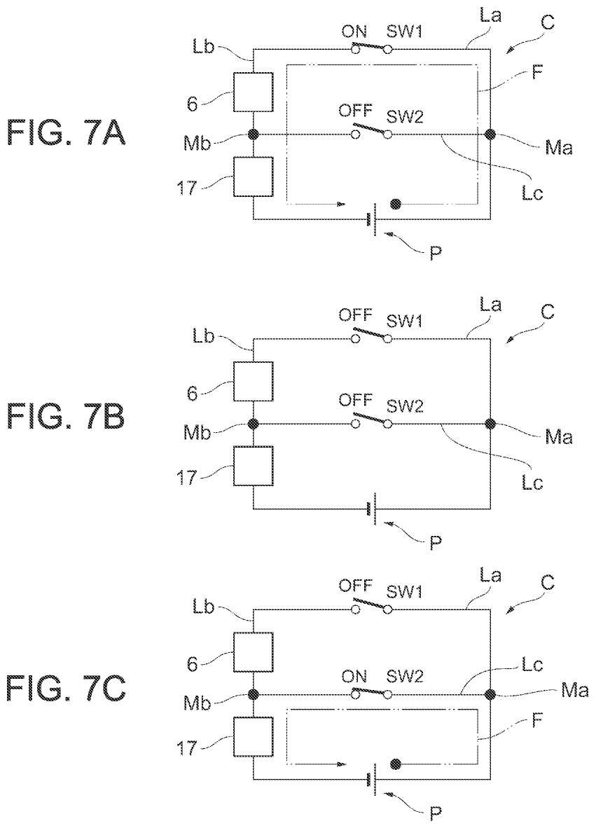

It is to be noted that FIGS. 4B and 6B show an aspect where a knob SW1a of the detection switch SW1 or a knob SW2a of the detection switch SW2 is tilted by the lens cover unit 4. By tilting the knob SW1a of the detection switch SW1 or the knob SW2a of the detection switch SW2, an ON/OFF state of a power circuit C can be switched. FIG. 7 shows a schematic diagram of the power circuit C.

As shown in FIG. 7, the power circuit C includes a power source P, power supply lines La, Lb, and Lc, the detection switches SW1 and SW2, the camera 6, and the microphone 17.

The power source P supplies electric power to the camera 6 and/or the microphone 17 through the detection switch SW1 or the detection switch SW2.

The power circuit C is provided with the first connection line La that electrically connects a positive electrode of the power source P and the detection switch SW1, the second connection line Lb that electrically connects a negative electrode of the power source P and the detection switch SW1, and the third connection line Lc that electrically connects between a connecting point Ma provided in the middle of the first connection line La and a connecting point Mb provided in the middle of the second connection line Lb through the detection switch SW2. The third connection line Lc electrically connects the first connection line La and the second connection line Lb so as to bypass the detection switch SW1.

The camera 6 and the microphone 17 are electrically connected to the middle of the second connection line Lb. Specifically, the camera 6 is connected between the connecting point Mb and the detection switch SW1 on the second connection line Lb, and the microphone 17 is connected between the connecting point Mb and the negative electrode of the power source P on the second connection line Lb. As described above, by causing the lens cover unit 4 to tilt the knob SW1a of the detection switch SW1 and the knob SW2a of the detection switch SW2, the power circuit C can be cut off, and thereby the camera 6 and the microphone 17 provided in the power circuit C can be put into the OFF state. How to switch the respective ON/OFF states of the camera 6 and the microphone 17 is described below. It is to be noted that in this specification, there is described an example where the power circuit C is configured to be cut off by tilting the knobs SW1a and SW2a; however, it is not limited to this example, and, for example, the power circuit C may be configured to be connected by tilting the knobs SW1a and SW2a.

As shown in FIG. 4A, in a case where the lens cover unit 4 is set in the first position, the lens cover unit 4 comes close to the end 311 of the long hole 31a of the bezel 31 (in FIG. 4A, the left end of the long hole 31a). In this first position, as shown in FIG. 4B, the transmission window 44 of the lens cover unit 4 overlaps with a lens 6a of the camera 6, and the lens cover unit 4 tilts the knob SW1a of the detection switch SW1 and puts the detection switch SW1 into the ON state. FIG. 7A shows an open/closed state of the power circuit C in this state. As shown in FIG. 7A, when the detection switch SW1 is in the ON state, and the detection switch SW2 is in the OFF state, electric power from the power source P can be supplied to the camera 6 and the microphone 17 (the flow of an electric current on a path indicated by an arrow F in the power circuit C shown in FIG. 7A can be generated), and the camera 6 and the microphone 17 can be turned ON. In this way, in a case where the lens cover unit 4 is set in the first position, the transmission window 44 of the lens cover unit 4 overlaps with the lens 6a of the camera 6, and at least one of the multiple detection switches SW1 and SW2 (in an example shown in FIGS. 4 and 7A, the detection switch SW1) is put into the ON state to activate the camera 6 and the microphone 17.

As shown in FIG. 5A, in a case where the lens cover unit 4 is set in the second position, the thick portion 42 of the lens cover unit 4 is located in the center of the long hole 31a of the bezel 31. In this second position, as shown in FIG. 5B, the lens cover unit 4 does not tilt the knobs SW1a and SW2a of the detection switches SW1 and SW2, and a portion of the lens cover unit 4 other than the transmission window 44 covers the lens 6a of the camera 6 (the transmission window 44 of the lens cover unit 4 does not overlap with the lens 6a of the camera 6). The lens cover unit 4 does not tilt any of the knobs SW1a and SW2a of the detection switches SW1 and SW2, thus the microphone 17 is put into the OFF state. FIG. 7B shows the open/closed state of the power circuit C in this state. As shown in FIG. 7B, when the detection switch SW1 is in the OFF state, and the detection switch SW2 is in the OFF state, the power circuit C is cut off, and no electric power is supplied from the power source P to the camera 6 and the microphone 17. In this way, in a case where the lens cover unit 4 is set in the second position, a portion of the lens cover unit 4 other than the transmission window 44 covers the lens 6a of the camera 6, and the multiple detection switches SW1 and SW2 are put into the OFF state to cut off the supply of electric power from the power source P to the camera 6 and the microphone 17.

In a state where the power circuit C is connected, the camera 6 and the microphone 17 are able to be turned ON when hacked by a third person through a network; however, by cutting off the power circuit C as shown in FIGS. 5 and 7B, the camera 6 and the microphone 17 become unable to be turned ON even when hacked. Accordingly, it is possible to strengthen the protection for user's privacy. It is to be noted that in the present embodiment, as shown in FIGS. 4 and 5, the above-described device control unit 111 activates the camera 6 on the basis of an output from the detecting device 16 that has detected that the lens cover unit 4 has moved from the second position (see FIG. 5) to the first position (see FIG. 4), and deactivates the camera 6 on the basis of an output from the detecting device 16 that has detected that the lens cover unit 4 has moved from the first position (see FIG. 4) to the second position (see FIG. 5).

Such a configuration solves a situation in which the camera 6 remains activated even after the lens cover unit 4 has been moved from the first position (see FIG. 4) to the second position (see FIG. 5) to cover the lens 6a of the camera 6. Accordingly, it is possible to reduce unnecessary power consumption of the camera 6. Furthermore, the above-described configuration makes an operation for activating or deactivating the camera 6 separately after the lens cover unit 4 is moved between the first position (see FIG. 4) and the second position (see FIG. 5) unnecessary or simple; therefore, it is possible to provide an electronic apparatus that offers high convenience while protecting privacy.

As shown in FIG. 6A, in a case where the lens cover unit 4 is set in the third position, the thick portion 42 of the lens cover unit 4 comes close to the end 312 of the long hole 31a of the bezel 31 (in FIG. 6A, the right end of the long hole 31a). In this third position, as shown in FIG. 6B, the lens cover unit 4 tilts the knob SW2a of the detection switch SW2 and puts the detection switch SW2 into the ON state. FIG. 7C shows the open/closed state of the power circuit C in this state. As shown in FIG. 7C, when the detection switch SW1 is in the OFF state, and the detection switch SW2 is in the ON state, electric power from the power source P is supplied only to the microphone 17 (the flow of an electric current on a path indicated by an arrow F in the power circuit C shown in FIG. 7C can be generated), and the microphone 17 can be turned ON. In this way, in a case where the lens cover unit 4 is set in the third position, a portion of the lens cover unit 4 other than the transmission window 44 covers the lens 6a of the camera 6, and at least one of the multiple detection switches SW1 and SW2 (in an example shown in FIGS. 6 and 7C, the detection switch SW2) is put into the ON state to activate the microphone 17.

Subsequently, a modification example of the layout of the detection switches SW1 and SW2 is described with reference to FIGS. 8 to 10. The modification example shown in FIGS. 8 to 10 differs from the example shown in FIGS. 4 to 6 in the layout of the detection switch SW2. Specifically, in the modification example shown in FIGS. 8 to 10, there is shown a configuration in which the detection switches SW1 and SW2 are installed side-by-side on one side of the camera 6 (in FIGS. 8 to 10, the left side of the camera 6).

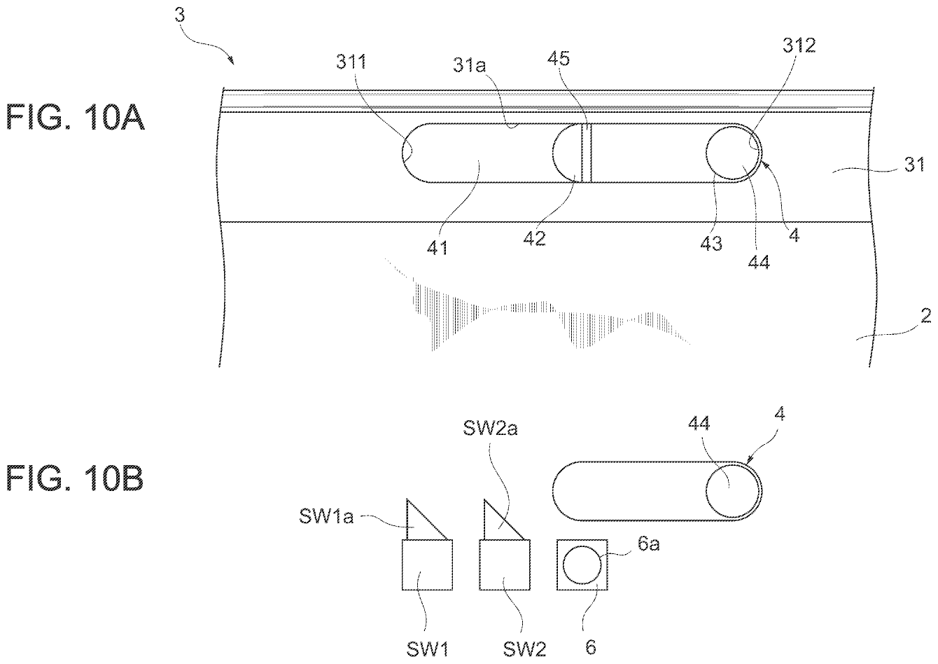

FIG. 8 shows a state where the lens cover unit 4 is set in the first position. FIG. 8A is a front view of the part II shown in FIG. 1. FIG. 8B is an explanatory diagram showing the ON/OFF states of the detection switches SW1 and SW2 when the lens cover unit 4 is in a position shown in FIG. 8A. FIG. 9 shows a state where the lens cover unit 4 is set in the third position. FIG. 9A is a front view of the part II shown in FIG. 1. FIG. 9B is an explanatory diagram showing the ON/OFF states of the detection switches SW1 and SW2 when the lens cover unit 4 is in a position shown in FIG. 9A. FIG. 10 shows a state where the lens cover unit 4 is set in the second position. FIG. 10A is a front view of the part II shown in FIG. 1. FIG. 10B is an explanatory diagram showing the ON/OFF states of the detection switches SW1 and SW2 when the lens cover unit 4 is in a position shown in FIG. 10A.

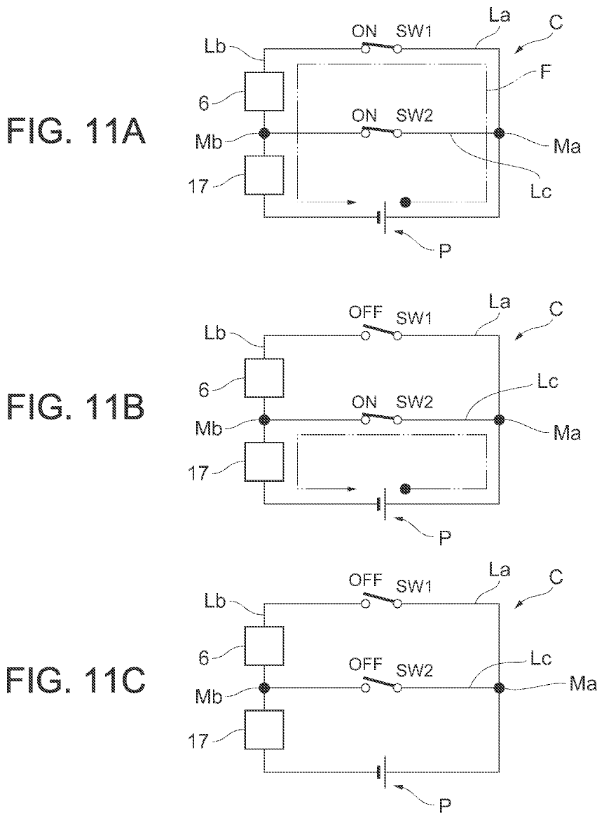

It is to be noted that FIGS. 8B and 9B show an aspect where the knob SW1a of the detection switch SW1 or the knob SW2a of the detection switch SW2 is tilted by the lens cover unit 4. As with the configuration described with reference to FIGS. 4B and 6B, in the modification example shown in FIGS. 8 to 10, the ON/OFF state of the power circuit C can be switched by tilting the knob SW1a of the detection switch SW1 or the knob SW2a of the detection switch SW2. FIG. 11 shows a schematic diagram of the power circuit C according to the modification example shown in FIGS. 8 to 10. The power circuit C shown in FIG. 11 has the same configuration as the power circuit C described with reference to FIG. 7; therefore, the same component is assigned the same reference numeral, and its description is omitted. How to switch the respective ON/OFF states of the camera 6 and the microphone 17 that are connected to the power circuit C shown in FIG. 11 is described below.

As shown in FIG. 8A, in a case where the lens cover unit 4 is set in the first position, the thick portion 42 of the lens cover unit 4 comes close to the end 311 of the long hole 31a of the bezel 31 (in FIG. 8A, the left end of the long hole 31a). In this first position, as shown in FIG. 8B, the transmission window 44 of the lens cover unit 4 overlaps with the lens 6a of the camera 6, and the knobs SW1a and SW2a of the multiple detection switches SW1 and SW2 are tilted by the lens cover unit 4. In this way, the detection switches SW1 and SW2 are put into the ON state by the knobs SW1a and SW2a being tilted. FIG. 11A shows the open/closed state of the power circuit C in this state. As shown in FIG. 11A, when the detection switch SW1 is in the ON state, and the detection switch SW2 is in the ON state, electric power from the power source P can be supplied to the camera 6 and the microphone 17 (the flow of an electric current on a path indicated by an arrow F in the power circuit C shown in FIG. 11A can be generated), and the camera 6 and the microphone 17 can be turned ON. In a case where the lens cover unit 4 is set in the first position in the modification example shown in FIGS. 8 to 10, the transmission window 44 of the lens cover unit 4 overlaps with the lens 6a of the camera 6, and at least one (in an example shown in FIG. 8, both) of the multiple detection switches SW1 and SW2 is put into the ON state to activate the camera 6 and the microphone 17.

As shown in FIG. 9A, in a case where the lens cover unit 4 is set in the third position, the thick portion 42 of the lens cover unit 4 is located in the center of the long hole 31a of the bezel 31. In this third position, as shown in FIG. 9B, the lens cover unit 4 tilts the knob SW2a of the detection switch SW2 and puts the detection switch SW2 into the ON state. FIG. 11B shows the open/closed state of the power circuit C in this state. As shown in FIG. 11B, when the detection switch SW1 is in the OFF state, and the detection switch SW2 is in the ON state, electric power from the power source P can be supplied only to the microphone 17 (the flow of an electric current on a path indicated by an arrow F in the power circuit C shown in FIG. 11B can be generated), and the microphone 17 can be turned ON. In this way, in a case where the lens cover unit 4 is set in the third position in the modification example shown in FIGS. 8 to 10, a portion of the lens cover unit 4 other than the transmission window 44 covers the lens 6a of the camera 6, and at least one of the multiple detection switches SW1 and SW2 (in an example shown in FIGS. 9 and 11B, the detection switch SW2) is put into the ON state to activate the microphone 17.

In the present embodiment, as shown in FIGS. 8 and 9, the above-described device control unit 111 activates the camera 6 on the basis of an output from the detecting device 16 that has detected that the lens cover unit 4 has moved from the third position (see FIG. 9) to the first position (see FIG. 8), and deactivates the camera 6 on the basis of an output from the detecting device 16 that has detected that the lens cover unit 4 has moved from the first position (see FIG. 8) to the third position (see FIG. 9).

According to such a configuration, as with the above-described example shown in FIGS. 4 to 6, it is possible to reduce unnecessary power consumption of the camera 6, and is also possible to provide an electronic apparatus that offers high convenience while protecting privacy.

As shown in FIG. 10A, in a case where the lens cover unit 4 is set in the second position, the thick portion 42 of the lens cover unit 4 comes close to the end 312 of the long hole 31a of the bezel 31 (in FIG. 10A, the right end of the long hole 31a). In this second position, as shown in FIG. 10B, a portion of the lens cover unit 4 other than the transmission window 44 covers the lens 6a of the camera 6, and the lens cover unit 4 does not tilt the knobs SW1a and SW2a of the detection switches SW1 and SW2. The lens cover unit 4 does not tilt any of the knobs SW1a and SW2a of the detection switches SW1 and SW2, thus the detection switches SW1 and SW2 are put into the OFF state. FIG. 11C shows the open/closed state of the power circuit C in this state. As shown in FIG. 11C, when the detection switch SW1 is in the OFF state, and the detection switch SW2 is in the OFF state, no electric power is supplied from the power source P to the camera 6 and the microphone 17, that is, the power circuit C is cut off. The microphone 17 is put into the OFF state. In this way, in a case where the lens cover unit 4 is set in the second position in the modification example shown in FIGS. 8 to 10, a portion of the lens cover unit 4 other than the transmission window 44 covers the lens 6a of the camera 6, and the multiple detection switches SW1 and SW2 are put into the OFF state to cut off the supply of electric power from the power source P to the camera 6 and the microphone 17.

By cutting off the power circuit C as shown in FIGS. 10 and 11C, the camera 6 and the microphone 17 become unable to be turned ON even when hacked by a third person through a network. Accordingly, it is possible to strengthen the protection for user's privacy.

It is to be noted that in the embodiment described above, there is described an example where the detection switches SW1 and SW2 have a function of switching the ON/OFF state of the microphone 17; however, it is not limited to this example. In the embodiment described above, the detection switch SW1 in the power circuit C shown in the drawings has a function of switching the ON/OFF states of the microphone 17 and the camera 6; however, the configurations of the power circuit C and the lens cover unit 4 are not limited to those shown in the drawings, and, for example, the detection switch SW2 may be configured to have the function of switching the ON/OFF states of the microphone 17 and the camera 6 by modifying the layout of the detection switch SW1 and the detection switch SW2 in the power circuit C and the configuration of the lens cover unit 4. Furthermore, for example, at least one of the detection switches SW1 and SW2 may be configured to be equipped with only the function of switching the ON/OFF state of the microphone 17 and not to be equipped with the function of switching the ON/OFF state of the camera 6.

Moreover, in the embodiment described above, there is described an aspect where the power circuit C is equipped with two detection switches; however, there may be another aspect where the power circuit C is equipped with one detection switch. For example, the power circuit C may be configured to be equipped with only the detection switch SW1 by modifying the example shown in FIG. 4 (the aspect where the detection switches SW1 and SW2 are provided on both sides of the camera 6), and, in this configuration, the camera 6 and the microphone 17 may be configured to be switched from the OFF state to the ON state by sliding the lens cover unit 4 from the second position to the first position. Likewise, the power circuit C may be configured to be equipped with only the detection switch SW1 by modifying the example shown in FIG. 8 (the aspect where the detection switches SW1 and SW2 are installed side-by-side on one side of the camera 6), and, in this configuration, the camera 6 and the microphone 17 may be configured to be switched from the OFF state to the ON state by sliding the lens cover unit 4 from the third position to the first position. It is to be noted that the number of the detection switches is not limited to the example shown in the drawings, and may be three or more.

As described with reference to FIGS. 4 to 11, the microphone 17 is put into the ON state or the OFF state in accordance with a combination of the operating state of a first switch (the detection switch SW1 is in the ON state or the OFF state) and the operating state of a second switch (the detection switch SW2 is in the ON state or the OFF state).

The embodiment described above is intended to facilitate understanding of the present invention and not to interpret the present invention in a limited way. Any flowcharts and sequences described in the embodiment, and any components included in the embodiment and their layout, material, condition, shape, size, etc. are not limited to those illustrated as an example and can be changed accordingly. Furthermore, components shown in different embodiments can be partially replaced or combined.

1. An electronic apparatus comprising:
a chassis;
a camera installed in the chassis;
a microphone installed in the chassis;
a switch that is in parallel with the camera to put the microphone into an ON state or an OFF state; and
a sliding member with a transmission window on its main body part, the transmission window being configured to let light through a lens of the camera,
wherein the sliding member is configured to move between a first position where the transmission window overlaps with the lens of the camera and the switch is put into ON state and a second position where a portion of the main body part other than the transmission window covers the lens and the switch is put into OFF state.

2. The electronic apparatus according to claim 1, wherein:
the switch includes at least a first switch and a second switch, and
the microphone is put into the ON state or the OFF state in accordance with a combination of an operating state of the first switch and an operating state of the second switch.

3. The electronic apparatus according to claim 1, wherein the sliding member is configured to move among the first position, the second position, and a third position where a portion of the main body part other than the transmission window covers the lens and the switch is put into the ON state

4. The electronic apparatus according to claim 3, further comprising a control unit configured to put the camera into the ON state or the OFF state,
wherein the control unit puts the camera from the ON state into the OFF state when the sliding member has been moved from the first position to the second position or from the first position to the third position.

5. The electronic apparatus according to claim 3, wherein:
the first and second switches are on both sides of the camera in a sliding direction of the sliding member,
the first position is a position where one of the first and second switches is in the ON state, and
the third position is a position where the other of the first and second switches is in the ON state.

6. The electronic apparatus according to claim 3, wherein:
the first and second switches are installed side-by-side on one side of the camera,
the first position is a position where the first and second switches are in the ON state, and
the third position is a position where one of the first and second switches is in the ON state.

7. The electronic apparatus according to claim 1, wherein electric power supplied to the microphone is cut off when the sliding member has moved to the second position.
